(19) United States
(12) Patent Application Publication
(10) Pub. No.: US 2016/0149152 A1
(43) Pub. Date: May 26, 2016

(54) ORGANIC LIGHT EMITTING DIODE DISPLAY

(71) Applicant: SAMSUNG DISPLAY CO., LTD., Yongin-City (KR)

(72) Inventors: Hyoung Kun KIM, Seoul (KR); Sam Il KHO, Seoul (KR); Dong Hyun KIM, Gwangju-si, Gyeonggi-do (KR); Mi Kyung KIM, Suwon-si, Gyeonggi-do (KR); Myeong-Suk KIM, Hwaseong-si, Gyeonggi-do (KR); Soung Wook KIM, Hwaseong-si, Gyeonggi-do (KR)

(21) Appl. No.: 14/707,623

(22) Filed: May 8, 2015

(30) Foreign Application Priority Data
Nov. 26, 2014 (KR) 10-2014-0166435

(51) Int. Cl. H01L 51/50; H01L 27/32

(52) U.S. Cl. CPC H01L 51/5008; H01L 27/3248; H01L 51/5088; H01L 51/5056; H01L 51/5004; H01L 51/5072; H01L 51/5092; H01L 51/504; H01L 51/5016; H01L 27/3262; H01L 2251/552; H01L 51/0072

(57) ABSTRACT

An organic light emitting diode display including a substrate; a thin film transistor on the substrate; a first electrode on the thin film transistor, the first electrode being electrically connected to the thin film transistor; a first layer on the first electrode; a buffer layer on the first layer; an emission layer on the buffer layer; a second layer on the emission layer; and a second electrode on the second layer.

### CROSS-REFERENCE TO RELATED APPLICATION

Korean Patent Application No. 10-2014-0166435, filed on Nov. 26, 2014, in the Korean Intellectual Property Office, and entitled: “Organic Light Emitting Diode Display,” is incorporated by reference herein in its entirety.

### BACKGROUND

1. Field

Embodiments relate to an organic light emitting diode (OLED) display.

2. Description of the Related Art

An organic light emitting diode display is a self-emissive display that displays an image using an organic light emitting diode for emitting light.

The OLED display may include a substrate, a pixel electrode on the substrate, an organic film including an emission layer (EML) on the pixel electrode, and an opposite or common electrode on the organic film. The organic layer may include an auxiliary layer facilitating injection or transferring of holes between the pixel electrode and the emission layer, and an auxiliary layer facilitating injection or transferring of electrons between the EML and the common electrode.

A driving principle of the OLED display having such a configuration will be described below. Once a voltage is applied between the pixel electrode and the common electrode, holes are injected from the pixel electrode into the emission layer via the auxiliary layer facilitating the injection or the transferring of the holes, and electrons are injected from the common electrode via the auxiliary layer facilitating injection or transferring of the electrons. The holes and the electrons injected into the emission layer are recombined in the emission layer to generate excitons, and the excitons are changed from an excited state to a ground state to thereby emit light. Light is emitted by the thus-generated energy, so that the OLED display displays an image.

The above information disclosed in this Background section is only for enhancement of understanding of the background and therefore it may contain information that does not form the prior art that is already known in this country to a person of ordinary skill in the art.

### SUMMARY

Embodiments are directed to an organic light emitting diode display.

The embodiments may be realized by providing an organic light emitting diode display including a substrate; a thin film transistor on the substrate; a first electrode on the thin film transistor, the first electrode being electrically connected to the thin film transistor; a first layer on the first electrode; a buffer layer on the first layer; an emission layer on the buffer layer; a second layer on the emission layer; and a second electrode on the second layer.

The first layer may include a hole injection layer and a hole transferring layer that are sequentially deposited from the substrate.

The buffer layer may have a HOMO value that is about 0.1 eV to about 0.4 eV greater than a HOMO value of the hole transferring layer.

The buffer layer may have a thickness of about 1 nm to about 15 nm.

The buffer layer may include a carbazole derivative, an arylamine derivative, or a combination thereof.

The hole transferring layer may include a material that is the same material as that of the hole injection layer and that is doped with a dopant of a P-type.

The hole transferring layer and the hole injection layer may include a compound represented by Chemical Formula 1:

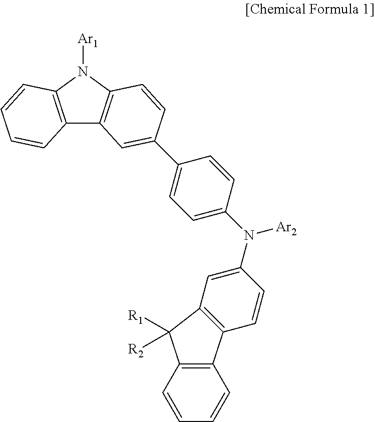

wherein, in Chemical Formula 1, R₁ and R₂ are each independently hydrogen, a C1-C30 substituted or non-substituted alkyl group, a C6 to C30 substituted or non-substituted aryl group, a C4-C30 substituted or non-substituted heteroaryl group, or a C6-C30 substituted or non-substituted condensed polycyclic group, adjacent groups of R₁ and R₂ being separate from one another or forming a coupled saturated or unsaturated carbon ring, Ar₁ and Ar₂ are each independently hydrogen, a non-substituted aryl group, or a substituted or non-substituted heteroaryl group, Ar₁ and Ar₂ each independently including about 1 to about 30 carbon atoms.

The buffer layer may have a HOMO value that is about 0.1 eV to about 0.4 eV greater than a HOMO value of the hole transferring layer.

The buffer layer may have a thickness of about 1 nm to about 15 nm.

The buffer layer may include a carbazole derivative, an arylamine derivative, or a compound thereof.

The second layer may include an electron transferring layer and an electron injection layer that are sequentially deposited from the substrate.

The emission layer may include a red emission layer, a green emission layer, and a blue emission layer.

The emission layer may have a thickness of about 10 nm to about 50 nm.

The hole injection layer may have a thickness of about 25 nm to about 35 nm, and the hole transferring layer may have a thickness of about 15 nm to about 25 nm.

### BRIEF DESCRIPTION OF THE DRAWINGS

Features will be apparent to those of skill in the art by describing in detail exemplary embodiments with reference to the attached drawings in which:

FIG. 1 illustrates a partial cross-sectional view focusing on a thin film transistor and an organic light emitting element used in an organic light emitting diode display according to an exemplary embodiment.

FIG. 2 illustrates an enlarged schematic cross-sectional view of a portion of the organic light emitting element of FIG. 1.

FIG. 3 and FIG. 4 illustrate graphs showing a measurement result of a flow characteristic of electrons and holes in an organic light emitting element according to an exemplary embodiment.

FIG. 5 illustrates a graph showing a measurement result of a lifespan of electrons and holes in an organic light emitting element according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

Now, an organic light emitting diode display according to an exemplary embodiment will be described with reference to accompanying drawings. The organic light emitting diode display may include a structure of the driving thin film transistor and the emission layer.

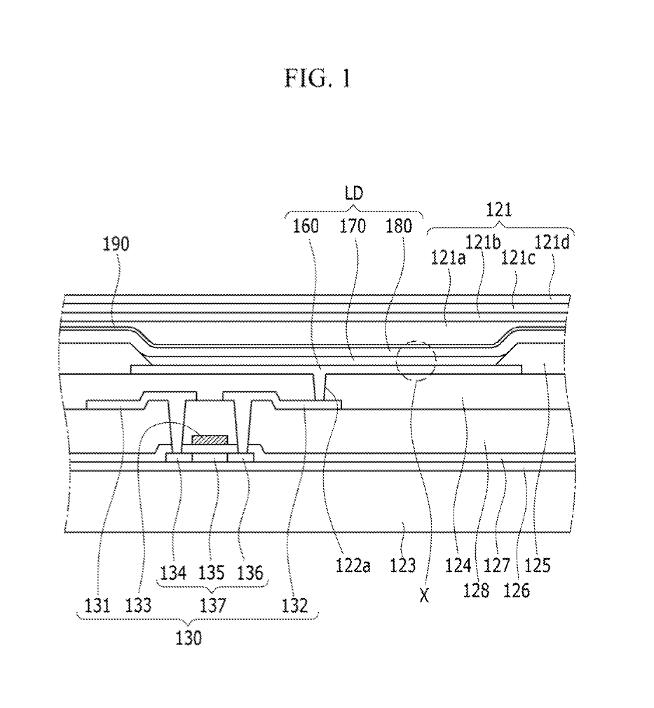

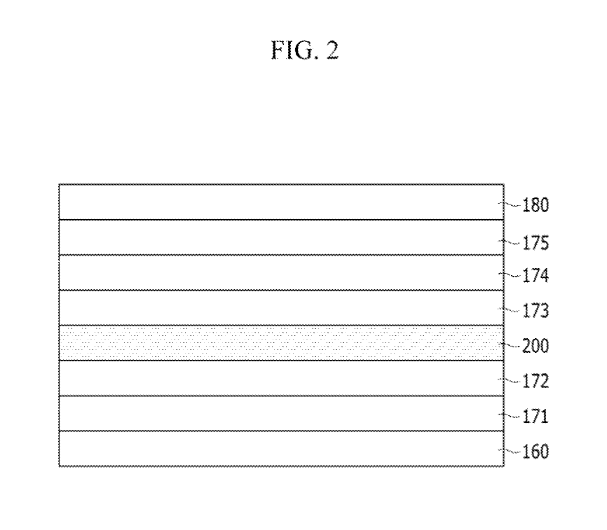

Referring to FIG. 1 and FIG. 2, the organic light emitting diode display according to an exemplary embodiment may include a substrate 123, a thin film transistor 130, a first electrode 160, first layers 171 and 172, a buffer layer 200, an emission layer 173, second layers 174 and 175, and a second electrode 180.

The first layers 171 and 172 may include, e.g., a hole injection layer 171 and a hole transferring layer 172, and the second layers 174 and 175 may include, e.g., an electron transferring layer 174 and an electron injection layer 175.

The substrate 123 may be formed as an insulating substrate made of, e.g., glass, quartz, ceramics, metal, plastic, or the like. In an implementation, the substrate 123 may be, e.g., a metallic substrate made of stainless steel.

A substrate buffer layer 126 may be formed on the substrate 123. The substrate buffer layer 126 may help prevent penetration of impurities and planarizes the surface.

In this case, the substrate buffer layer 126 may be made of various materials capable of performing the functions. For example, one of a silicon nitride (SiNx) layer, a silicon oxide (SiOx) layer, or a silicon oxynitride (SiOxNy) layer may be used as the substrate buffer layer 126. In an implementation, the substrate buffer layer 126 may be omitted according to a kind of substrate 123 and process conditions.

A driving semiconductor layer 137 may be formed on the substrate buffer layer 126. The driving semiconductor layer 137 may be formed as a polysilicon layer. The driving semiconductor layer 137 may include a channel region 135 in which impurities are not doped, and a source region 134 and a drain region 136 in which the impurities are doped at respective sides of the channel region 135. In this case, the doped ion materials may be P-type impurities such as boron (B), and B₂H₆ may be used. Here, the impurities vary according to a kind of thin film transistor.

A gate insulating layer 127 made of a silicon nitride (SiNx) or a silicon oxide (SiOx) may be formed on the driving semiconductor layer 137. A gate wire including a driving gate electrode 133 may be formed on the gate insulating layer 127. In addition, the driving gate electrode 133 may overlap at least a part of the driving semiconductor layer 137, e.g., the channel region 135.

An interlayer insulating layer 128 covering the driving gate electrode 133 may be formed on the gate insulating layer 127. Contact holes exposing the source region 134 and the drain region 136 of the driving semiconductor layer 137 may be formed in the gate insulating layer 127 and the interlayer insulating layer 128. The interlayer insulating layer 128 may be formed by using a ceramic-based material such as a silicon nitride (SiNx) or a silicon oxide (SiOx), like the gate insulating layer 127.

A data wire including a driving source electrode 131 and a driving drain electrode 132 may be formed on the interlayer insulating layer 128. The driving source electrode 131 and the driving drain electrode 132 may be connected with the source region 134 and the drain region 136 of the driving semiconductor layer 137 through the contact holes 128a formed in the interlayer insulating layer 128 and the gate insulating layer 127, respectively.

As such, the driving thin film transistor 130 including the driving semiconductor layer 137, the driving gate electrode 133, the driving source electrode 131, and the driving drain electrode 132 may be formed. In an implementation, the configuration of the driving thin film transistor 130 may be variously modified as a suitable configuration.

A planarization layer 124 covering the data wire may be formed on the interlayer insulating layer 128. The planarization layer 124 may remove and planarize a step in order to help increase emission efficiency of the organic light emitting element to be formed thereon. The planarization layer 124 may have an electrode via hole 122a exposing a part of the drain electrode 132.

The planarization layer 124 may be made of one or more materials of a polyacrylate resin, an epoxy resin, a phenolic resin, a polyamide resin, a polyimide resin, an unsaturated polyester resin, a polyphenylene ether resin, a polyphenylene sulfide resin, or benzocyclobutene (BCB).

In an implementation, one of the planarization layer 124 and the interlayer insulating layer 128 may be omitted.

A first electrode of the organic light emitting element, e.g., a pixel electrode 160, may be formed on the planarization layer 124. The organic light emitting diode device may include a plurality of pixel electrodes 160 that are disposed for every one of the plurality of pixels, respectively. In this case, the plurality of pixel electrodes 160 may be spaced apart from each other. The pixel electrode 160 may be connected to the drain electrode 132 through the electrode via hole 122a of the planarization layer 124.

A pixel defining layer 125 having an opening exposing the pixel electrode 160 may be formed on the planarization layer 124. For example, the pixel defining layer 125 may have a plurality of openings formed for each pixel. In this case, the organic emission layer 170 may be formed for each opening formed by the pixel defining layer 125. Accordingly, a pixel area in which each organic emission layer is formed by the pixel defining layer 125 may be defined.

In this case, the pixel electrode 160 may correspond to the opening of the pixel defining layer 125. In an implementation, the pixel electrode 160 may not necessarily be disposed only in the opening of the pixel defining layer 125, but may be disposed below the pixel defining layer 125 so that a part of the pixel electrode 160 overlaps with the pixel defining layer 125.

The pixel defining layer 125 may be made of resin such as a polyacrylate resin and a polyimide resin, a silica-based inorganic material, or the like.

An organic emission layer 170 may be formed on the pixel electrode 160. The structure of the organic emission layer 170 will be described below.

A second electrode, e.g., a common electrode 180, may be formed on the organic emission layer 170. As such, the organic light emitting diode LD including the pixel electrode 160, the organic emission layer 170, and the common electrode 180 may be formed.

In this case, each of the pixel electrode 160 and the common electrode 180 may be made of a transparent conductive material or a transflective or reflective conductive material. According to a kind of materials forming the pixel electrode 160 and the common electrode 180, the organic light emitting diode device may be a top emission type, a bottom emission type, or a double-sided emission type.

An overcoat 190 covering and protecting the common electrode 180 may be formed as an organic layer on the common electrode 180.

A thin film encapsulation layer 121 may be formed on the overcoat 190. The thin film encapsulation layer 121 may encapsulate and protect the organic light emitting element LD and a driving circuit part formed on the substrate 123 from the external environment.

The thin film encapsulation layer 121 may include organic encapsulation layers 121a and 121c and inorganic encapsulation layers 121b and 121d which are alternately laminated. In FIG. 1, e.g., a case where two organic encapsulation layers 121a and 121c and two inorganic encapsulation layers 121b and 121d are alternately laminated to configure the thin film encapsulation layer 121 is illustrated, but it is not limited thereto.

Next, the organic light emitting element according to an embodiment will be described with reference to FIG. 2. FIG. 2 illustrates an enlarged schematic cross-sectional view of a portion of the organic light emitting element of FIG. 1.

The organic light emitting element (a portion X of FIG. 1) according to an exemplary embodiment may have a structure in which a first electrode 160, a hole injection layer 171, the hole transferring layer 172, a buffer layer 200, an emission layer 173, an electron transferring layer 174, an electron injection layer 175, and a second electrode 180 are sequentially laminated.

For example, the organic emission layer 170 of FIG. 1 may include the hole injection layer 171, the hole transferring layer 172, the buffer layer 200, the emission layer 173, the electron transferring layer 174, and the electron injection layer 175 of FIG. 2.

In this case, the hole injection layer 171 may be disposed on the first electrode 160. In an implementation, the hole injection layer 171 may include a suitable layer to help improve the injection of holes from the first electrode 160 into the hole transferring layer 172. The hole injection layer 171 may be formed of, e.g., copper phthalocyanine (CuPc), poly(3,4-ethylenedioxythiophene) (PEDOT), polyaniline (PANI), or N,N′-diphenyl-N,N′-di-[4-(N,N-diphenyl-amino)phenyl]benzidine (NPNPB).

The thickness of the hole injection layer 171 may be, e.g., 25 μm to about 35 μm.

The hole transferring layer 172 may be disposed on the hole injection layer 171. The hole transferring layer 172 may facilitate smooth transport of the holes transferred from the hole injection layer 171. In an implementation, the hole transferring layer 172 may be formed of or include, e.g., N,N-di(1-naphthyl)-N,N-di(phenyl)benzidine (NPD), N,N′-bis(3-methylphenyl)-N,N′-bis(phenyl) (TPD), s-TAD, or 4,4′,4″-tris(N-3-methylphenyl-N-phenyl-amino)-triphenylamine (MTDATA).

In an implementation, the hole transferring layer 172 may include, e.g., a compound represented by the following Chemical Formula 1.

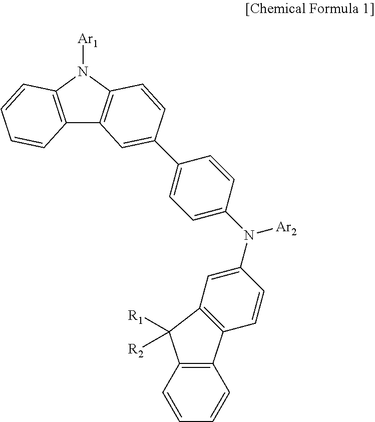

In Chemical Formula 1, R₁ and R₂ may each independently be or include, e.g., hydrogen, a C1-C30 substituted or non-substituted alkyl group, a C6 to C30 substituted or non-substituted aryl group, a C4-C30 substituted or non-substituted heteroaryl group, or a C6-C30 substituted or non-substituted condensed polycyclic group. In an implementation, adjacent groups of or among R₁ and R₂ may be separate from one another or may be bound to form a coupled saturated or unsaturated carbon ring.

Ar₁ and Ar₂ may each independently be or include, e.g., a non-substituted aryl group or a substituted or non-substituted hetero aryl group. In an implementation, Ar₁ and Ar₂ may each independently have a carbon number of about 1 to about 30, or may not be present (e.g., Ar₁ and/or Ar₂ may be hydrogen).

In an implementation, the hole injection layer 171 may include a material applied or doped with a P-type dopant that is the same material as that of the material included in the hole transferring layer 172 such that the driving voltage of the organic light emitting element is decreased, thereby improving the hole injection characteristic. In an implementation, the hole transferring layer 172 may include a material doped with a dopant, e.g., a P-type dopant.

In this case, a thickness of the hole transferring layer 172 may be, e.g., about 15 nm to about 25 nm.

In an implementation, the hole injection layer 171 and the hole transferring layer 172 may have the laminated structure, or the hole injection layer 171 and the hole transferring layer 172 may be formed of a singular layer.

The buffer layer 200 may be formed on the hole transferring layer 172. In the organic light emitting element according to an exemplary embodiment, the buffer layer 200 may help control an amount of holes transmitted from the first electrode 160 to the emission layer 173, and simultaneously an amount of electrons transmitted from the emission layer 173 to the hole transferring layer 172.

For example, the buffer layer 200 perform the functions of hole control and electron blocking to facilitate the combination of the holes and the electrons in the emission layer 173, and blocks the electrons that could otherwise penetrate into the hole transferring layer 172, thereby preventing damage to the hole transferring layer 172 due to the electrons.

In order to help decrease the driving voltage of the organic light emitting element and to improve the injection characteristic of the holes and the electrons, the hole injection layer 171 and the hole transferring layer 172 having high conductivity may be applied, or the P-type dopant may be applied to the hole transferring layer 172. In this case, the lifespan of the organic light emitting element may be reduced due to the over-injected holes or electrons. Also, the over-injected electrons may be accumulated to the emission layer 173 and then may penetrate into the hole transferring layer 172 such that the lifespan may be reduced due to the damage to the hole transferring layer 172.

The hole transferring layer 172 and the emission layer 173 may have a HOMO (highest occupied molecular orbital) value difference of about 0.5 eV such that an energy barrier is generated by the HOMO value difference, and the holes and the electrons that are not combined between the hole transferring layer 172 and the emission layer 173 may be eliminated.

Accordingly, by forming the buffer layer 200 between the hole transferring layer 172 and the emission layer 173, while decreasing the HOMO value difference of the hole transferring layer 172 and the emission layer 173, over-injection of the holes into the emission layer 173 may be reduced and/or prevented and, simultaneously, the electrons accumulated inside the emission layer 173 may be prevented from penetrating into the hole transferring layer 172, thereby improving the entire lifespan of the organic light emitting element.

Further, the balance of the holes and the electrons may be formed or maintained by the buffer layer 200 such that the emission efficiency of the organic light emitting element may also be improved.

In an implementation, the buffer layer 200 may have a HOMO value between the HOMO values of the hole transferring layer 172 and the emission layer 173 to help smooth or compensate for the HOMO value difference of the hole transferring layer 172 and the emission layer 173. In an implementation, the buffer layer 200 may have a HOMO value that is, e.g., about 0.1 eV, larger than the HOMO value of the hole transferring layer 172.

In an implementation, when considering a HOMO value difference of about 0.5 eV between the hole transferring layer 172 and the emission layer 173, the HOMO value of the buffer layer 200 may be, e.g., about 0.1 eV to about 0.4 eV, larger than the HOMO value of the hole transferring layer.

For example, the emission efficiency may be slightly improved when the buffer layer 200 has a smaller difference than the hole transferring layer 172, e.g., of less than 0.1 eV.

The thickness of the buffer layer 200 may be, e.g., about 1 nm to about 15 nm. In an implementation, the thickness of the buffer layer 200 may be, e.g., about 10 nm.

Maintaining the thickness of the buffer layer 200 at about 1 nm or greater may help ensure that the lifespan and/or the efficiency characteristic are sufficiently improved by the buffer layer 200. Maintaining the thickness of the buffer layer 200 at about 15 nm or less may help prevent slowing of hole injection into emission layer 173 such that the emission efficiency characteristic may be maintained. For example, by maintaining the thickness of the buffer layer 200 at about 1 nm to about 15 nm, the emission efficiency and the lifespan of the organic light emitting diode display may be maximized.

The buffer layer 200 may be formed of or may include, e.g., a carbazole derivative (carbazole-containing compound), an arylamine derivative (arylamine-containing compound), or a compound or combination thereof.

The emission layer 173 may include a light-emitting material for displaying a predetermined color. For example, the emission layer 173 may display a primary color such as blue, green, or red, or a combination thereof.

The thickness of the emission layer 173 may be, e.g., about 15 μm to about 25 μm.

The emission layer 173 may include a host and a dopant. The emission layer 173 may include materials for emitting red, green, blue, and white light, and may be formed by using a phosphorescent or fluorescent material.

In a case where the emission layer 173 emits red light, it may include, e.g., a host material having carbazole biphenyl (CBP) or 1,3-bis(carbazol-9-yl) (mCP), and may be formed of, e.g., a phosphorescent material containing a dopant having at least one of a group consisting of PIQIr(acac) (bis(1-phenylisoquinoline)acetylacetonate iridium), PQIr(acac) (bis(1-phenylquinoline)acetylacetonate iridium), PQIr (tris(1-phenylquinoline)iridium), or PtOEP (platinum octaethylporphyrin).

In a case where the emission layer 173 emits green light, it may include, e.g., a host material having CBP or mCP, and may be formed of, e.g., a phosphorescent material containing a dopant having Ir(ppy)₃ (fac-tris(2-phenylpyridine)iridium) or a phosphorescent material containing a dopant having Alq3 (tris(8-hydroxyquinolino)aluminum).

In a case where the emission layer 173 emits green light, it may include, e.g., a host material having CBP or mCP, and may be formed of, e.g., a phosphorescent material containing a dopant (4,6-F₂ppy)₂Irpic. In an implementation, the emission layer 173 may be formed of, e.g., a phosphorescent material containing any one selected from a group consisting of spiro-DPVBi, spiro-6P, distyryl benzene (DSB), distyryl arylene (DSA), a PFO-based polymer, or a PPV-based polymer.

The electron transferring layer 174 may be disposed on the emission layer 173. In this case, the electron transferring layer 174 may facilitate transfer of electrons from the second electrode 180 to the emission layer 173. The electron transferring layer 174 may help prevent the holes injected from the first electrode 160 from moving to the second electrode 180 through the emission layer 173. For example, the electron transferring layer 174 may serve as a hole blocking layer to help improve combination of the holes and electrons in the emission layer 173.

In this case, the electron transferring layer 174 may be formed of or may include, e.g., Alq3 (tris(8-hydroxyquinolino)aluminum), PBD, TAZ, spiro-PBD, BAlq, or SAlq.

The electron injection layer 175 may be formed on the electron transferring layer 174. The electron injection layer 175 may be a suitable layer to help improve the injection of the electrons from the second electrode 180 into the electron transferring layer 174. The electron injection layer 175 may include, e.g., Alq3, LiF, a gallium mixture (Ga complex), or PBD.

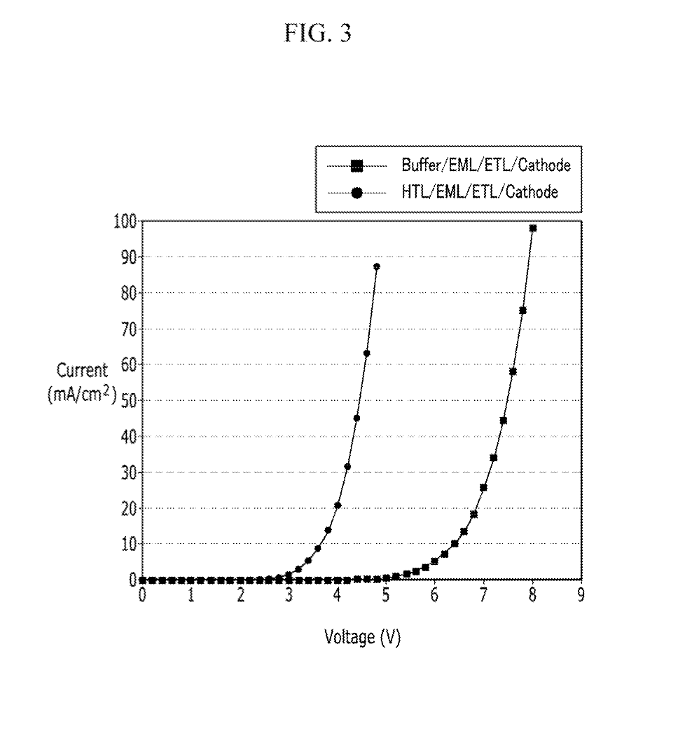

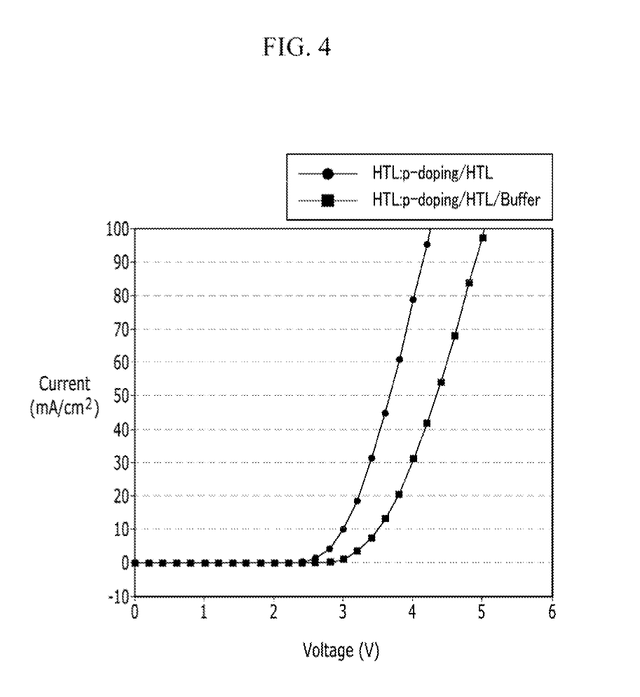

FIG. 3 and FIG. 4 illustrate graphs showing a measurement result of a flow characteristic of electrons and holes in an organic light emitting element according to an exemplary embodiment.

First, a flow characteristic of the electrons will be described with reference to FIG. 3.

To measure the change of the flow characteristic of the electrons by the buffer layer, as an exemplary embodiment, the ITO layer, the buffer layer, the electron transferring layer, the electron injection layer, and the second electrode may be sequentially deposited, the current may be applied to the second electrode, and then the voltage in the ITO layer may be measured, and a Comparative Example may be tested by the same method as the exemplary embodiment except for the presence of the buffer layer.

An X-axis of FIG. 3 represents a voltage (V), and a Y-axis represents a current (mA/cm²).

As shown in FIG. 3, in the case where the buffer layer is included, the voltage may be higher, and it may be confirmed that the buffer layer blocks a portion of the electron flow.

Next, the flow characteristic of the hole will be described with reference to FIG. 4.

To measure the change of the flow characteristic of the hole by the buffer layer, as an exemplary embodiment, the ITO layer, the buffer layer, the hole transferring layer, the hole injection layer, and the first electrode may be sequentially deposited, the current may be applied to the first electrode, and then the voltage in the ITO layer may be measured, and a comparative example may be tested by the same method as the exemplary embodiment, except for the presence of the buffer layer.

The X-axis of FIG. 4 represents the voltage (V), and the Y-axis represents a current (mA/cm²).

As shown in FIG. 4, in the case where the buffer layer is included, the voltage is higher, and it may be seen that the buffer layer helps to block a portion of the hole flow.

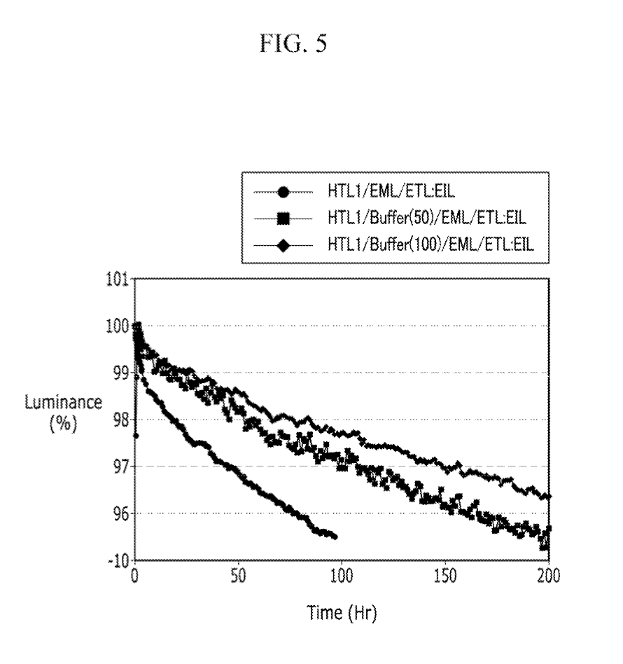

FIG. 5 illustrates a graph showing a measurement result of a lifespan of electrons and holes in an organic light emitting element according to an exemplary embodiment.

In FIG. 5, the X-axis represents passage of time (h), and the Y-axis represents a luminance (%).

To test the lifespan difference of the organic light emitting diode display according to the presence of the buffer layer and the thickness of the buffer layer, the luminance change according to the time passage may be measured for an organic light emitting diode display including a 5 nm thick buffer layer, an organic light emitting diode display including a 10 nm thick buffer layer, and a Comparative Example of the organic light emitting diode display without the buffer layer.

As shown in FIG. 5, compared with the organic light emitting diode display without the buffer layer, the luminance reduction according to the time passage may be small in the organic light emitting diode display applied with the buffer layer, thereby improving the lifespan.

For example, compared with the organic light emitting diode display including a 5 nm thick buffer layer, the lifespan of the organic light emitting diode display including a 10 nm thick buffer layer may be further improved.

Next, the characteristic of the organic light emitting diode display according to an exemplary embodiment will be described with reference to Table 1.

Table 1 is a table showing a characteristic of an organic light emitting diode display according to an exemplary embodiment and a Comparative Example.

The characteristic may be measured for the organic light emitting diode display including a 5 nm thick buffer layer, the organic light emitting diode display including a 10 nm thick buffer layer, and the organic light emitting diode display without the buffer layer as a Comparative Example.

TABLE 1

| Existence of | | | Current | Power | X-color | Y-color | Conversion | |
|---|---|---|---|---|---|---|---|---|
| buffer layer | Driving | Current | efficiency | efficiency | coordinate | coordinate | efficiency | Lifespan |
| (thickness) | voltage (V) | (mA/cm²) | (Cd/A) | (Im/W) | (CIE_x) | (CIE_y) | (Cd/A/y) | (h) |
| No | 4.3 | 13.1 | 4.7 | 3.4 | 0.143 | 0.047 | 100.3 | 45 |
| Yes (5 nm) | 4.1 | 12.0 | 5.3 | 4.1 | 0.142 | 0.049 | 109.1 | 98 |
| Yes (10 nm) | 4.1 | 12.3 | 4.9 | 3.8 | 0.143 | 0.046 | 105.9 | 148 |

As may be seen in Table 1, in the case of the organic light emitting diode display including the buffer layer described above, the conversion efficiency may be comparably higher such that it may be seen that the emission efficiency is excellent compared with the Comparative Example, and the lifespan may also be improved.

Table 2 shows a characteristic of the organic light emitting diode display according to the HOMO value of the buffer layer.

The characteristics of the organic light emitting diode display including the buffer layer having a HOMO value that is 0.1 eV larger than the HOMO value of the hole transferring layer, an organic light emitting diode display including the buffer layer having a HOMO value that is 0.03 eV larger than the HOMO value of the hole transferring layer as a first Comparative Example, and an organic light emitting diode display including the buffer layer having a HOMO value that is 0.05 eV larger than the HOMO value of the hole transferring layer as a second Comparative Example may be measured.

TABLE 2

| Buffer layer thickness | | | | | | |
|---|---|---|---|---|---|---|
| (HOMO value difference for a hole | Driving | Current | X-color | Y-color | Conversion | |
| transferring layer) | voltage | efficiency | coordinate | coordinate | efficiency | Lifespan |
| 5 nm (+0.1 eV) | 4.1 | 5.3 | 0.142 | 0.049 | 109.1 | 98 |
| 10 nm (+0.1 eV) | 4.1 | 4.9 | 0.143 | 0.046 | 105.9 | 148 |
| 5 nm (+0.03 eV) | 4.1 | 4.5 | 0.145 | 0.044 | 102.4 | 62 |
| 5 nm (+0.05 eV) | 4.1 | 4.5 | 0.144 | 0.044 | 103.8 | 53 |

As shown in Table 2, in the case of the organic light emitting diode display including the buffer layer having the HOMO value difference of less than 0.1 eV relative to the hole transferring layer, it may be seen that the conversion efficiency and the lifespan may appear as low values, compared with the organic light emitting diode display including the buffer layer having the HOMO value difference of 0.1 eV relative to the hole transferring layer.

Accordingly, the buffer layer may help improve both the lifespan and the emission efficiency when a difference in the HOMO value of the buffer layer and the HOMO value of the hole transferring layer is greater than about 0.1 eV.

By way of summation and review, when holes and electrons are imbalanced, the organic film may be damaged, and thereby a characteristic of the organic light emitting element may be unstable such that emission efficiency may be decreased and a lifespan may be shortened.

As described above, according to an exemplary embodiment, the lifespan and the emission efficiency of the organic light emitting diode display may be increased by the buffer layer formed in the organic layer.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

### DESCRIPTION OF SYMBOLS

| | |
|---|---|
| 123: substrate | 130: thin film transistor |
| 160: first electrode | 180: second electrode |
| 171: hole injection layer | 172: hole transferring layer |
| 173: emission layer | 174: electron transferring layer |
| 175: electron injection layer | 200: buffer layer |

What is claimed is:

1. An organic light emitting diode display, comprising:
a substrate;
a thin film transistor on the substrate;
a first electrode on the thin film transistor, the first electrode being electrically connected to the thin film transistor;
a first layer on the first electrode;
a buffer layer on the first layer;
an emission layer on the buffer layer;
a second layer on the emission layer; and
a second electrode on the second layer.

2. The organic light emitting diode display as claimed in claim 1, wherein the first layer includes a hole injection layer and a hole transferring layer that are sequentially deposited from the substrate.

3. The organic light emitting diode display as claimed in claim 2, wherein the buffer layer has a HOMO value that is about 0.1 eV to about 0.4 eV greater than a HOMO value of the hole transferring layer.

4. The organic light emitting diode display as claimed in claim 2, wherein the buffer layer has a thickness of about 1 nm to about 15 nm.

5. The organic light emitting diode display as claimed in claim 2, wherein the buffer layer includes a carbazole derivative, an arylamine derivative, or a combination thereof.

6. The organic light emitting diode display as claimed in claim 2, wherein the hole transferring layer includes a material that is the same material as that of the hole injection layer and that is doped with a dopant of a P-type.

7. The organic light emitting diode display as claimed in claim 6, wherein the hole transferring layer and the hole injection layer include a compound represented by Chemical Formula 1: 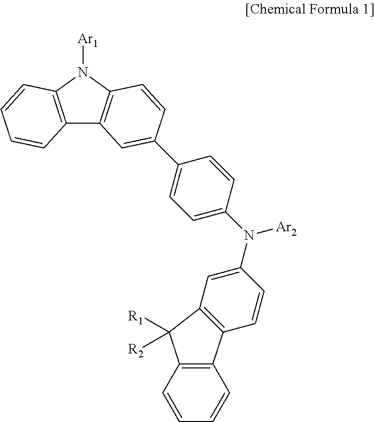
wherein, in Chemical Formula 1,
R₁ and R₂ are each independently hydrogen, a C1-C30 substituted or non-substituted alkyl group, a C6 to C30 substituted or non-substituted aryl group, a C4-C30 substituted or non-substituted heteroaryl group, or a C6-C30 substituted or non-substituted condensed polycyclic group, adjacent groups of R₁ and R₂ being separate from one another or forming a coupled saturated or unsaturated carbon ring,
Ar₁ and Ar₂ are each independently hydrogen, a non-substituted aryl group, or a substituted or non-substituted heteroaryl group, Ar₁ and Ar₂ each independently including about 1 to about 30 carbon atoms.

8. The organic light emitting diode display as claimed in claim 7, wherein the buffer layer has a HOMO value that is about 0.1 eV to about 0.4 eV greater than a HOMO value of the hole transferring layer.

9. The organic light emitting diode display as claimed in claim 8, wherein the buffer layer has a thickness of about 1 nm to about 15 nm.

10. The organic light emitting diode display as claimed in claim 9, wherein the buffer layer includes a carbazole derivative, an arylamine derivative, or a combination thereof.

11. The organic light emitting diode display as claimed in claim 2, wherein the second layer includes an electron transferring layer and an electron injection layer that are sequentially deposited from the substrate.

12. The organic light emitting diode display as claimed in claim 11, wherein the emission layer includes a red emission layer, a green emission layer, and a blue emission layer.

13. The organic light emitting diode display as claimed in claim 12, wherein the emission layer has a thickness of about 10 nm to about 50 nm.

14. The organic light emitting diode display as claimed in claim 13, wherein:
the hole injection layer has a thickness of about 25 nm to about 35 nm, and
the hole transferring layer has a thickness of about 15 nm to about 25 nm.
